(19) United States
(12) Patent Application Publication
(10) Pub. No.: US 2012/0133010 A1
(43) Pub. Date: May 31, 2012

(54) SEMICONDUCTOR DEVICE AND METHOD OF MANUFACTURING THE SEMICONDUCTOR DEVICE

(75) Inventor: Toshiaki KOMUKAI, Oita (JP)

(73) Assignee: KABUSHIKI KAISHA TOSHIBA, Tokyo (JP)

(21) Appl. No.: 13/238,313

(22) Filed: Sep. 21, 2011

(30) Foreign Application Priority Data
Nov. 29, 2010 (JP) 2010-265371

(51) Int. Cl. H01L 31/0232; H01L 23/48

(52) U.S. Cl. 257/432; 257/774; 438/70; 257/435; 257/E23.011; 257/E31.127

(57) ABSTRACT

According to one embodiment, a semiconductor device includes: a through-hole formed in a semiconductor layer; a through-hole insulting layer formed on a sidewall of the through-hole to retract from a front surface of the semiconductor layer; a through-electrode embedded in the through-hole via the through-hole insulating layer; and a sidewall insulating film formed on a sidewall of the through-electrode to be embedded in a retracting section of the through-hole insulating layer.

### CROSS-REFERENCE TO RELATED APPLICATIONS

This application is based upon and claims the benefit of priority from the prior Japanese Patent Application No. 2010-265371, filed on Nov. 29, 2010; the entire contents of which are incorporated herein by reference.

### FIELD

Embodiments described herein relate generally to a semiconductor device and a method of manufacturing the semiconductor device.

### BACKGROUND

To realize a three-dimensional structure of a semiconductor device, there is a method of providing a through-electrode in a semiconductor layer in which a wire is formed. When the through-electrode is provided in the semiconductor layer, a through-hole insulating layer that insulates the semiconductor layer and the through-electrode is formed on a sidewall of a through-hole. If the through-hole insulating layer retracts from the front surface of the semiconductor layer, in some case, a conductor is embedded in a retracting section of the through-hole insulating layer and insulating properties for the semiconductor layer and the through-electrode are deteriorated.

### BRIEF DESCRIPTION OF THE DRAWINGS

FIG. 1 is a sectional view of a schematic configuration of a semiconductor device according to a first embodiment;

FIG. 2A is a sectional view for explaining a method of manufacturing a semiconductor device according to a second embodiment;

FIG. 2B is a sectional view for explaining the method of manufacturing a semiconductor device according to the second embodiment;

FIG. 2C is a sectional view for explaining the method of manufacturing a semiconductor device according to the second embodiment;

FIG. 3A is a sectional view for explaining the method of manufacturing a semiconductor device according to the second embodiment;

FIG. 3B is a sectional view for explaining the method of manufacturing a semiconductor device according to the second embodiment;

FIG. 3C is a sectional view for explaining the method of manufacturing a semiconductor device according to the second embodiment;

FIG. 4A is a sectional view for explaining the method of manufacturing a semiconductor device according to the second embodiment;

FIG. 4B is an enlarged sectional view of a section A shown in FIG. 4A;

FIG. 5 is a sectional view for explaining a method of manufacturing a semiconductor device according to a third embodiment;

FIG. 6A is a sectional view for explaining the method of manufacturing a semiconductor device according to a third embodiment;

FIG. 6B is an enlarged sectional view of a section B shown in FIG. 6A;

FIG. 7A is a sectional view for explaining a method of manufacturing a semiconductor device according to a fourth embodiment; and

FIG. 7B is a sectional view for explaining the method of manufacturing a semiconductor device according to the fourth embodiment.

### DETAILED DESCRIPTION

In general, according to one embodiment, a semiconductor device includes a through-hole, a through-hole insulating layer, a through-electrode, and a sidewall insulating film. The through-hole is formed in a semiconductor layer. The through-hole insulting layer is formed on a sidewall of the through-hole to retract from the front surface of the semiconductor layer. The through-electrode is embedded in the through-hole via the through-hole insulating layer. The sidewall insulating film is formed on a sidewall of the through-electrode to be embedded in a retracting section of the through-hole insulating layer.

Exemplary embodiments of a semiconductor device and a method of manufacturing the semiconductor device will be explained below in detail with reference to the accompanying drawings. The present invention is not limited to the following embodiments.

### First Embodiment

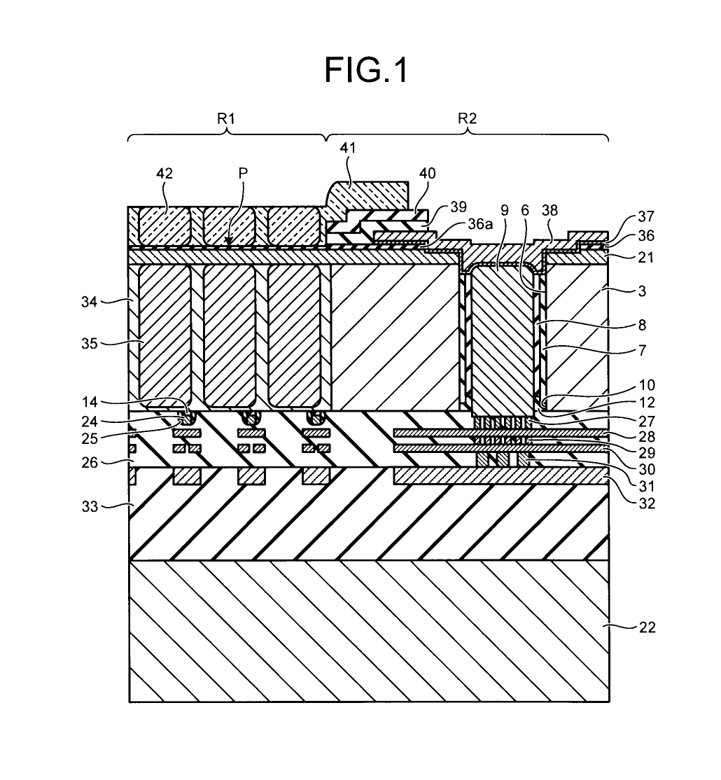

FIG. 1 is a sectional view of a schematic configuration of a semiconductor device according to a first embodiment. In the following explanation, as an example, a back-illuminated CMOS image sensor is used as the semiconductor device. However, the present invention is not limited to the back-illuminated CMOS image sensor and can be applied to a semiconductor device having a three-dimensional structure other than the back-illuminated CMOS image sensor.

In FIG. 1, a pixel region R1 and a peripheral region R2 are provided in a semiconductor layer 3. A shield layer 21 is provided on the rear surface of the semiconductor layer 3. As the semiconductor layer 3 and the shield layer 21, for example, Si, Ge, SiGe, GaAs, InP, GaP, GaN, SiC, GaInAsP, or the like can be used. As the semiconductor layer 3, an N-type epitaxial semiconductor can be used. As the shield layer 21, a p⁺-type epitaxial semiconductor can be used.

In the semiconductor layer 3 in the pixel region R1, impurity diffusion layers 35 are formed for respective pixels. Therefore, photodiodes are formed for the respective pixels as photoelectric conversion sections. In an example shown in FIG. 1, a method of forming PN diodes as the photoelectric conversion sections is explained. However, the photoelectric conversion sections are not limited to the PN diodes and can be, for example, PIN diodes. As the impurity diffusion layers 35, an N-type epitaxial semiconductor can be used.

Pixel separation layers 34 that separate the photoelectric conversion sections for the respective pixels are formed among the impurity diffusion layers 35. A light receiving surface P is provided on the rear surface side of the photoelectric conversion sections. As the pixel separation layers 34, a P⁺-type epitaxial semiconductor can be used.

In the pixel region R1, an organic film 41 is provided on the rear surface side of the photoelectric conversion sections. In the organic film 41, color filters 42 are formed for the respective pixels.

In the pixel region R1, gate electrodes 24 are formed on the front surface side of the semiconductor layer 3 via gate insulating films 14. Sidewall insulating films 25 are formed on sidewalls of the gate electrodes 24. For example, a silicon oxide film can be used as the gate insulating films 14, a polysilicon film can be used as the gate electrodes 24, and a silicon oxide film or a silicon nitride film can be used as the sidewall insulating films 25.

The gate electrodes 24 can form readout circuits that read out signals from the photoelectric conversion sections. As the readout circuits, for example, a row selection transistor, an amplification transistor, a reset transistor, a readout transistor, and a floating diffusion can be provided for the respective pixels.

On the other hand, in the peripheral region R2, a through-hole 6 is formed in the semiconductor layer 3 and the shield layer 21. A through-electrode 9 is embedded in the through-hole 6 via through-hole insulating layers 7 and 8. The through-hole insulating layers 7 and 8 are formed to retract from the front surface of the semiconductor layer 3. The through-electrode 9 can be projected from the front surface of the semiconductor layer 3. A recess 10 corresponding to retracting sections of the through-hole insulating layers 7 and 8 is formed between the semiconductor layer 3 and the through-electrode 9. A sidewall insulating film 12 embedded in the recess 10 is formed on a sidewall of the through-electrode 9. For example, polysilicon can be used as the through-electrode 9, a silicon oxide film can be used as the through-hole insulating layer 7, and a silicon nitride film can be used as the through-hole insulating layer 8. For example, a silicon oxide film or a silicon nitride film can be used as the sidewall insulating film 12.

On the rear surface side of the semiconductor layer 3, an insulating film 36 is formed on the shield layer 21 and a pad electrode 38 is formed on the insulating film 36 via a barrier metal film 37. An opening 36a for exposing the through-electrode 9 is formed in the insulating film 36. The pad electrode 38 is electrically connected to the through-electrode 9 via the opening 36a. For example, a silicon oxide film or a silicon nitride film can be used as the insulating film 36, a stacked structure of Ti and TIN can be used as the barrier metal film 37, and an Al film can be used as the pad electrode 38.

Further, in the peripheral region R2, protective films 39 and 40 are formed on the insulating film 36. Openings 39a and 40a for exposing the pad electrode 38 are respectively formed in the protective films 39 and 40. For example, a silicon oxide film can be used as the protective film 39 and a silicon nitride film can be used as the protective film 40.

In the pixel region R1 and the peripheral region R2, an interlayer insulating layer 26 is formed on the front surface side of the semiconductor layer 3. In the interlayer insulating layer 26, wires 28 and 30 are embedded for respective layers. A wire 32 is formed on the interlayer insulating layer 26. The wire 28 and the through-electrode 9 are connected to each other via embedded electrodes 27. The wires 28 and 30 are connected to each other via embedded electrodes 29. The wires 30 and 32 are connected to each other via embedded electrodes 31.

A protective film 33 is formed on the wire 32. A supporting substrate 22 is provided on the protective film 33. For example, a silicon oxide film can be used as the protective film 33 and a silicon substrate can be used as the supporting substrate 22. The supporting substrate 22 can be stuck to the protective film 33 by SiO₂ direct joining.

The sidewall insulating film 12 is embedded in the recess 10 between the semiconductor layer 3 and the through-electrode 9, whereby a conductive material can be prevented from entering the recess 10 during formation of the gate electrode 24. Therefore, a leak path can be prevented from being formed between the semiconductor layer 3 and the through electrode 9. Even when the through-hole insulating layers 7 and 8 retract from the front surface of the semiconductor layer 3, it is possible to secure insulating properties for the semiconductor layer 3 and the through-electrode 9.

In the embodiment explained above, a method of using the polysilicon as the through-electrode 9 is explained. However, besides the polysilicon, W, Cu, or the like can be used. A method of using the silicon oxide film as the through-hole insulating layer 7 and using the silicon nitride film as the through-hole insulating layer 8 is explained. However, only one of the through-hole insulating layers 7 and 8 can be used as a single layer.

### Second Embodiment

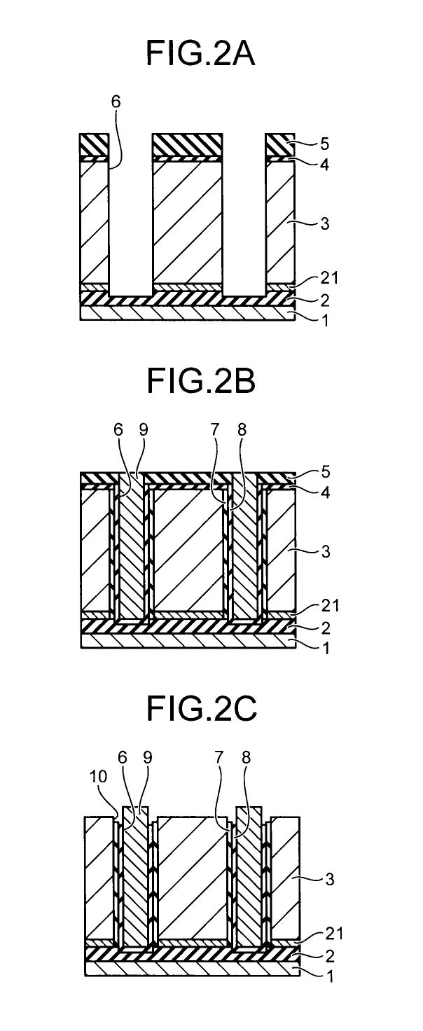

FIGS. 2A to 2C, 3A to 3C, and 4A and 4B are sectional views for explaining a method of manufacturing a semiconductor device according to a second embodiment.

In FIG. 2A, the shield layer 21 and the semiconductor layer 3 are sequentially provided on the semiconductor substrate 1 via a BOX layer 2. As the semiconductor substrate 1 on which the shield layer 21 and the semiconductor layer 3 are sequentially provided via the BOX layer 2, an SOI substrate can be used. For example, Si can be used as a material of the semiconductor substrate 1 and a silicon oxide film can be used as a material of the BOX layer 2. When boron is doped in the semiconductor substrate 1, the shield layer 21 can be formed by diffusing boron from the semiconductor substrate 1 to the semiconductor layer 3.

After a silicon oxide film 4 is formed on the semiconductor layer 3 by a method such as thermal oxidation of the semiconductor layer 3, a stopper layer 5 is stacked on the silicon oxide film 4 by a method such as the CVD. For example, a silicon nitride film can be used as the stopper layer 5. Through-holes 6 are formed in the stopper layer 5, the silicon oxide film 4, the semiconductor layer 3, and the shield layer 21 by using a photolithography technology and a dry etching technology. For example, the depth of the through-holes 6 can be set to about 4 micrometers and the diameter of the through-holes 6 can be set to about 600 nanometers.

Subsequently, as shown in FIG. 2B, the through-hole insulating layers 7 and 8 are sequentially stacked over the entire surface on the stopper layer 5 by a method such as the CVD to cover sidewalls of the through-holes 6. A silicon oxide film is used as the through-hole insulating layer 7 and a silicon nitride film is used as the through-hole insulating layer 8. This makes it possible to improve insulating properties for the through-hole insulating layers 7 and 8 while reducing the stress of the silicon nitride film applied to the semiconductor layer 3.

Through-electrodes 9 are formed on the stopper layer 5 by a method such as plating or the CVD to fill the through-holes 6.

As shown in FIG. 2C, the through-electrodes 9 are reduced in thickness by a method such as the CMP, whereby the through-electrodes 9 on the stopper layer 5 are removed. Thereafter, etching of the stopper layer 5 and the silicon oxide film 4 is performed, whereby the stopper layer 5 and the silicon oxide film 4 on the semiconductor layer 3 are removed. To suppress damage to the front surface of the semiconductor layer 3, it is desirable to remove the stopper layer 5 and the silicon oxide film 4 with wet etching. When the stopper layer 5 and the silicon oxide film 4 are etched, the through-hole insulating layers 7 and 8 are also etched and retract from the front surface of the semiconductor layer 3. Consequently, recesses 10 between the semiconductor layer 3 and the through-electrodes 9 are formed. When the stopper layer 5 and the silicon oxide film 4 are etched, the through-electrodes 9 project onto the semiconductor layer 3 by the thickness of the stopper layer 5 and the silicon oxide film 4. For example, the width of the recesses 10 can be set to about 30 nanometers and a projection amount of the through-electrodes 9 can be set to about 50 to 70 nm.

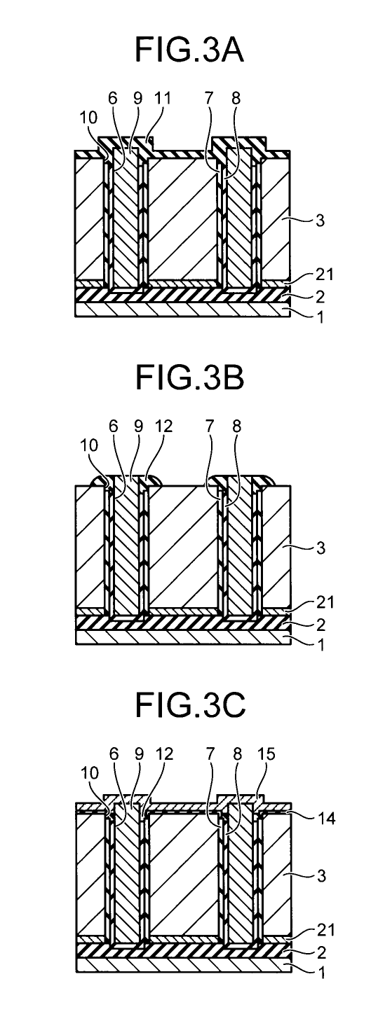

As shown in FIG. 3A, the insulating film 11 is formed on the semiconductor layer 3 by a method such as the CVD to cover the through-electrodes 9.

As shown in FIG. 3B, the semiconductor layer 3 is exposed by performing anisotropic etching of the insulating film 11. Sidewall films 12 embedded in the recesses 10 are formed on the sidewalls of the through-electrodes 9. For example, the thickness of the insulating film 11 can be set to about 150 to 200 nanometers. A silicon oxide film or a silicon nitride film can be used as the insulating film 11. To suppress damage to the front surface of the semiconductor layer 3, after the insulating film 11 is reduced in thickness halfway by anisotropic etching, the semiconductor layer 3 can be exposed by wet etching of the insulating film 11.

As shown in FIG. 3C, the sidewall insulating film 12 extending beyond the recesses 10 is removed. The gate insulating film 14 is formed on the semiconductor layer 13 by a method such as thermal oxidation of the semiconductor layer 3. At this point, the position in the height direction of the surface of the sidewall insulating film 12 can be set equal to the position in the height direction of the front surface of the semiconductor layer 3. For example, the thickness of the gate insulating film 14 can be set to about 2 nanometers. A conductive film 15 is formed on the gate insulating film 14 by a method such as the CVD. For example, a polysilicon film can be used as the conductive film 15.

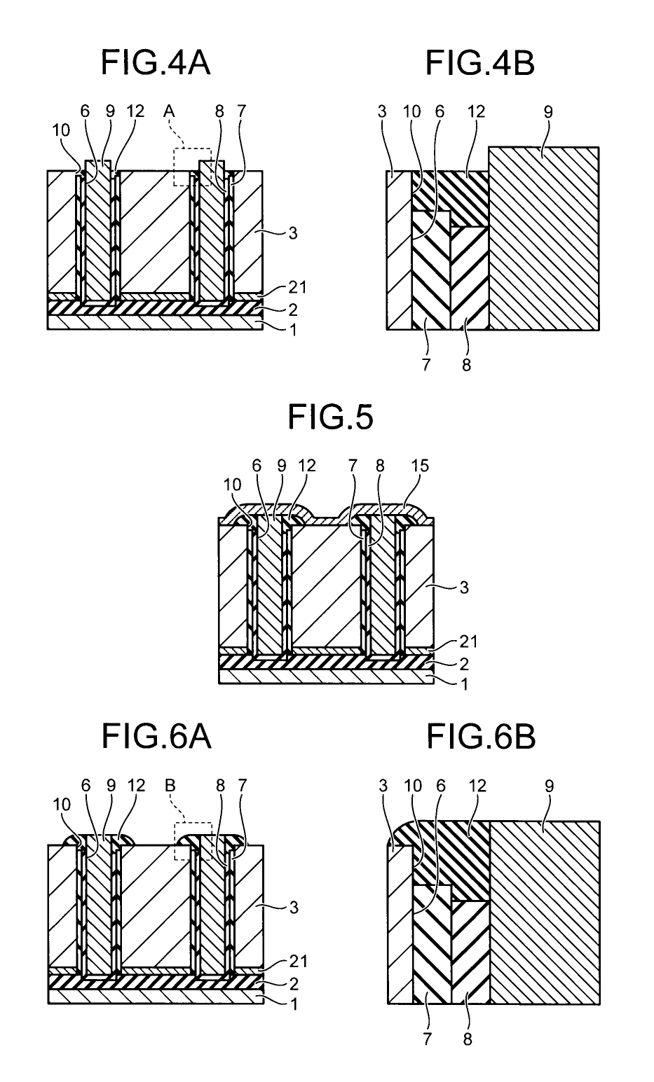

As shown in FIGS. 4A and 4B, the conductive film 15 is subjected to patterning using the photolithography technology and the dry etching technology, whereby the conductive film 15 on the through-electrodes 9 is removed and the gate electrodes 24 shown in FIG. 1 are formed on the semiconductor layer 3.

Consequently, the sidewall insulating film 12 can be embedded in the recesses 10 between the semiconductor layer 13 and the through-electrodes 9, the conductive film 15 can be prevented from entering the recesses 10, and a leak path can be prevented from being formed between the semiconductor layer 3 and the through-electrodes 9. Therefore, even when the through-hole insulating layers 7 and 8 retract from the front surface of the semiconductor layer 3, it is possible to secure insulating properties for the semiconductor layer 3 and the through-electrodes 9.

### Third Embodiment

FIGS. 5 and 6A and 6B are sectional views for explaining a method of manufacturing a semiconductor device according to a third embodiment.

In FIG. 5, after the step shown in FIG. 3B, the sidewall insulating film 12 extending beyond the recesses 10 is not removed and the gate insulating film 14 and the conductive film 15 are sequentially formed on the semiconductor layer 3 while the sidewall insulating film 12 is left in projecting sections of the through-electrodes 9.

Subsequently, as shown in FIGS. 6A and 6B, the conductive film 15 is subjected to patterning using the photolithography technology and the dry etching technology, whereby the conductive film 15 on the through-electrodes 9 is removed and the gate electrodes 24 shown in FIG. 1 are formed on the semiconductor layer 3. At this point, the sidewall insulating film 12 can extend onto the semiconductor layer 3. The position in the height direction of the surface of the sidewall insulating film 12 can be set equal to the position in the height direction of the surfaces of the through-electrodes 9.

The sidewall insulating film 12 is left in the projecting sections of the through-electrodes 9. This makes it possible to prevent the conductive film 15 from adhering to the sidewalls of the through-electrodes 9 and improve insulating properties for the semiconductor layer 3 and the through-electrodes 9.

### Fourth Embodiment

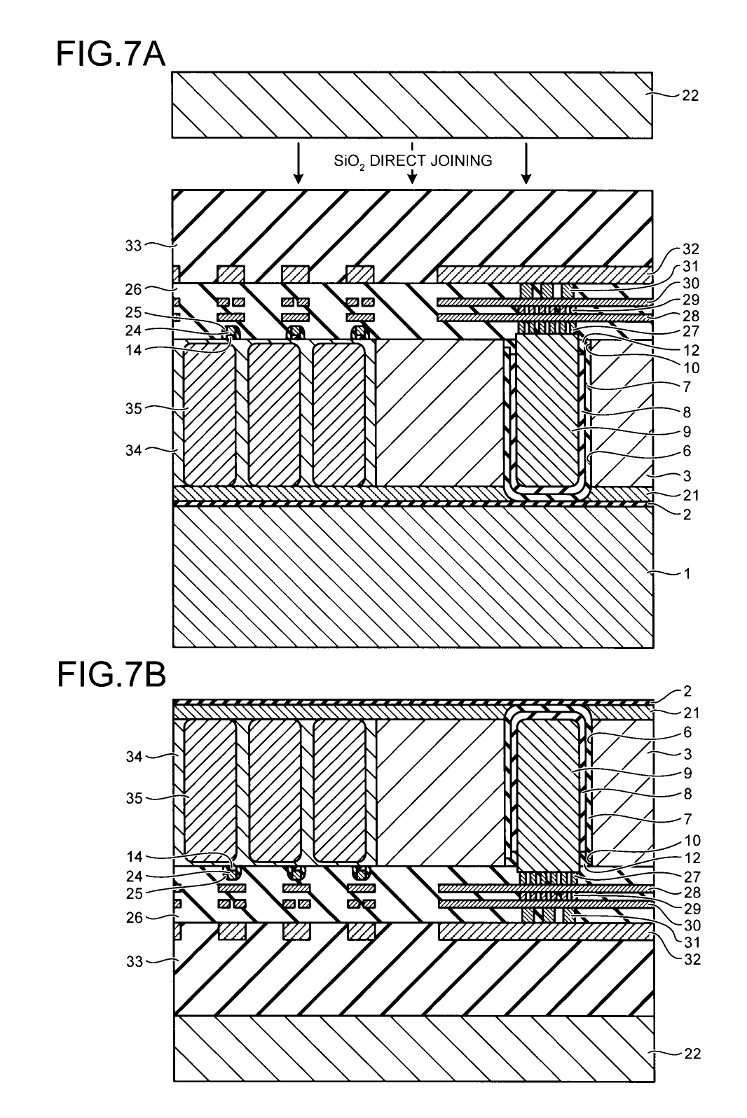

FIGS. 7A and 7B are sectional views for explaining a method of manufacturing a semiconductor device according to a fourth embodiment.

In FIG. 7A, the through-electrode 9 and the gate electrodes 24 are formed in the semiconductor layer 3 in the steps shown in FIGS. 2A to 2C, 3A to 3C, and 4. The impurity diffusion layers 35 and the pixel separation layers 34 are formed in the semiconductor layer 3, whereby photoelectric conversion sections are formed for respective pixels.

Thereafter, after the embedded electrodes 27, 29, and 31 and the wires 28, 30, and 32 are formed in the interlayer insulating layer 26, the protective film 33 is formed on the interlayer insulating layer 26 and the supporting substrate 22 is joined to the protective film 33.

Subsequently, as shown in FIG. 7B, CMP of the semiconductor substrate 1 is performed using the BOX layer 2 as a stopper layer, whereby the semiconductor substrate 1 is removed. Thereafter, etching of the BOX layer 2 is performed, whereby the BOX layer 2 is removed from the rear surface of the semiconductor layer 3. The through-hole insulating layers 7 and 8 on the rear surface side of the semiconductor layer 3 are removed, whereby the through-electrode 9 is exposed to the rear surface side of the semiconductor layer 3.

After the insulating film 36 is formed on the shield layer 21, the barrier metal film 37 and the pad electrode 38 connected to the through-electrode 9 via the opening 36a are formed. Thereafter, after the protective films 39 and 40 are formed in the peripheral region R2, the color filters 42 are formed in the pixel region R1 for the respective pixels.

The sidewall insulating film 12 is embedded in the recess 10 between the semiconductor layer 3 and the through-electrode 9. Therefore, even when the through-electrode 9 is provided in a back-illuminated CMOS image sensor, a leak path can be prevented from being formed between the semiconductor layer 3 and the through-electrode 9. Therefore, it is possible to secure insulating properties for the semiconductor layer 3 and the through-electrode 9.

In the embodiment explained above, a method of forming a back-illuminated CMOS image sensor using an SOI substrate is explained. However, the present invention can be applied to a method of forming a back-illuminated CMOS image sensor using a bulk epitaxial substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a through-hole formed in a semiconductor layer;
a through-hole insulting layer formed on a sidewall of the through-hole to retract from a front surface of the semiconductor layer;
a through-electrode embedded in the through-hole via the through-hole insulating layer; and
a sidewall insulating film formed on a sidewall of the through-electrode to be embedded in a retracting section of the through-hole insulating layer.

2. The semiconductor device according to claim 1, wherein the through-hole insulating layer is a stacked structure of a silicon oxide film and a silicon nitride film.

3. The semiconductor device according to claim 1, wherein a position in a height direction of a surface of the sidewall insulating film is equal to a position in the height direction of the front surface of the semiconductor layer.

4. The semiconductor device according to claim 1, wherein the through-electrode projects from the front surface of the semiconductor layer.

5. The semiconductor device according to claim 4, wherein the sidewall insulating film extends to the front surface of the semiconductor layer to cover a sidewall of a projecting section of the through electrode.

6. A semiconductor device comprising:
a semiconductor layer in which a photoelectric conversion section is formed;
a readout circuit formed on a front surface side of the semiconductor layer and configured to read out a signal from the photoelectric conversion section;
a light receiving surface provided on a rear surface side of the photoelectric conversion section;
a through-hole formed in the semiconductor layer;
a through-hole insulating layer formed on a sidewall of the through-hole to retract from the front surface of the semiconductor layer;
a through-electrode embedded in the through-hole via the through-hole insulating layer;
a sidewall insulating film formed on a sidewall of the through-electrode to be embedded in a retracting section of the through-hole insulating layer;
a wire formed on the front surface side of the semiconductor layer; and
a pad electrode formed on a rear surface side of the semiconductor layer and connected to the wire via the through-electrode.

7. The semiconductor device according to claim 6, wherein the through-hole insulating layer is a stacked structure of a silicon oxide film and a silicon nitride film.

8. The semiconductor device according to claim 6, wherein a position in a height direction of a surface of the sidewall insulating film is equal to a position in the height direction of the front surface of the semiconductor layer.

9. The semiconductor device according to claim 6, wherein the through-electrode projects from the front surface of the semiconductor layer.

10. The semiconductor device according to claim 9, wherein the sidewall insulating film extends to the front surface of the semiconductor layer to cover a sidewall of a projecting section of the through electrode.

11. The semiconductor device according to claim 6, further comprising a shield layer formed on the rear surface of the semiconductor layer.

12. The semiconductor device according to claim 11, further comprising:
a protective film formed on the front surface side of the semiconductor layer and configured to protect the readout circuit; and
a supporting substrate provided on the protective film.

13. The semiconductor device according to claim 6, wherein the photoelectric conversion section is formed for each pixel.

14. The semiconductor device according to claim 13, further comprising a color filter provided on the rear surface side of the photoelectric conversion section and formed for the each pixel.

15. A method of manufacturing a semiconductor device comprising:
forming a stopper layer on a semiconductor layer;
forming a through-hole in the stopper layer and the semiconductor layer;
forming a through-hole insulating layer on a sidewall of the through-hole;
embedding a through-electrode in the through-hole via the through-hole insulating layer;
removing the stopper layer; and
forming a sidewall insulating film on a sidewall of the through-electrode to be embedded in a section where the through-hole insulating layer retracts when the stopper layer is removed.

16. The method of manufacturing a semiconductor device according to claim 15, wherein the semiconductor layer is formed on a semiconductor substrate via a BOX layer.

17. The method of manufacturing a semiconductor device according to claim 16, further comprising:
forming a photoelectric conversion section in the semiconductor layer for each pixel;
forming, on a front surface side of the semiconductor layer, a protective film for protecting the front surface of the semiconductor layer; and
joining a supporting substrate to the protective film.

18. The method of manufacturing a semiconductor device according to claim 17, further comprising:
performing, after joining the supporting substrate to the protective film, CMP of the semiconductor substrate using the BOX layer as a stopper layer to thereby remove the semiconductor substrate; and
removing the BOX layer from a rear surface of the semiconductor layer.

19. The method of manufacturing a semiconductor device according to claim 18, further comprising:
removing the through-hole insulating layer on the rear surface side of the semiconductor layer to thereby expose the through-electrode to the rear surface side of the semiconductor layer; and
forming a pad electrode connected to the through-electrode on the rear surface side of the semiconductor layer.

20. The method of manufacturing a semiconductor device according to claim 19, further comprising forming a color filter on the rear surface side of the semiconductor layer for the each pixel.
